(19) United States
(12) Patent Application Publication
(10) Pub. No.: US 2014/0361245 A1
(43) Pub. Date: Dec. 11, 2014

(54) LED CHIP AND METHOD OF MANUFACTURING THE SAME

(71) Applicant: ADVANCED OPTOELECTRONIC TECHNOLOGY, INC., Hsinchu Hsien (TW)

(72) Inventors: CHIA-HUI SHEN, Hukou (TW); TZU-CHIEN HUNG, Hukou (TW)

(21) Appl. No.: 14/299,208

(22) Filed: Jun. 9, 2014

(30) Foreign Application Priority Data
Jun. 11, 2013 (CN) 201310230275X

(51) Int. Cl. H01L 33/00; H01L 33/12; H01L 33/20; H01L 33/06

(52) U.S. Cl. CPC H01L 33/005; H01L 33/06; H01L 33/12; H01L 33/20
USPC 257/13; 438/47; 438/22

(57) ABSTRACT

A method of manufacturing an LED chip includes: providing a laminated structure with a nanoimprinted material coated thereon; providing an imprinted mold with a patterned structure for pressing and curing the nanoimprinted material, removing the imprinted mold, etching the nanoimprinted material and the laminated structure; and forming electrodes on the etched laminated structure. An LED chip is also provided.

### FIELD

The disclosure relates to a method of manufacturing an LED (light emitting diode) chip, and particularly to a nanoimprint method to manufacture the LED chip via nanoimprint, and an LED chip provided by the method.

### BACKGROUND

LEDs have many advantages, such as high luminosity, low operational voltage, low power consumption, compatibility with integrated circuits, easy driving, long term reliability, and environmental friendliness, which have promoted the wide use of LEDs as a light source.

Typically, an inclined side surface of an LED chip etched by photolithography is used for weakening total reflection and improving the light extraction efficiency.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present LED chip and method of manufacturing the LED chip. Moreover, in the drawings, like reference numerals designate corresponding parts throughout the several views.

FIG. 1 is a flow chart of a method of manufacturing an LED chip in accordance with an exemplary embodiment of the present disclosure.

FIG. 2 is a cross-section view showing a laminated structure and a nanoimprinted material coated thereon in accordance with the exemplary embodiment of the present disclosure by a block 41 of the method of FIG. 1.

FIG. 3 is a cross-section view showing the nanoimprinted material coated on the laminated structure and a mold incorporating the laminated structure in accordance with a first embodiment of the present disclosure by a block 42 of the method of FIG. 1.

FIGS. 4 and 5 are cross-section views showing the nanoimprinted material cured and a mold removed in accordance with the first embodiment of the present disclosure by a block 43 of the method of FIG. 1.

FIGS. 6 and 7 are cross-section views showing the nanoimprinted material and the laminated structure etched in accordance with the first embodiment of the present disclosure by a block 44 of the method of FIG. 1.

FIG. 8 is a cross-section view showing electrodes formed on the laminated structure in accordance with the first embodiment of the present disclosure by a block 45 of the method of FIG. 1.

FIG. 9 is a cross-section view showing a mold in accordance with a second embodiment of the present disclosure by the block 42 of the method of FIG. 1.

FIG. 10 is a cross-section view of an LED chip manufactured by the mold in FIG. 9.

### DETAILED DESCRIPTION OF EMBODIMENTS

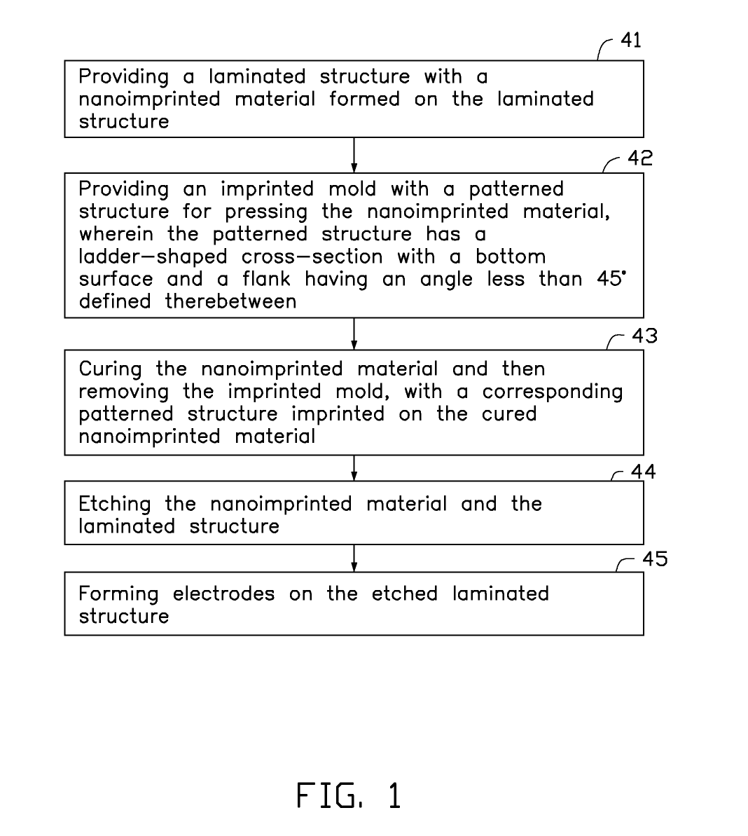

FIG. 1 is a flow chart of a method of manufacturing an LED chip in accordance with an exemplary embodiment of the present disclosure. The method will be referred to as Block 41, Block 42, Block 43, Block 44 and Block 45.

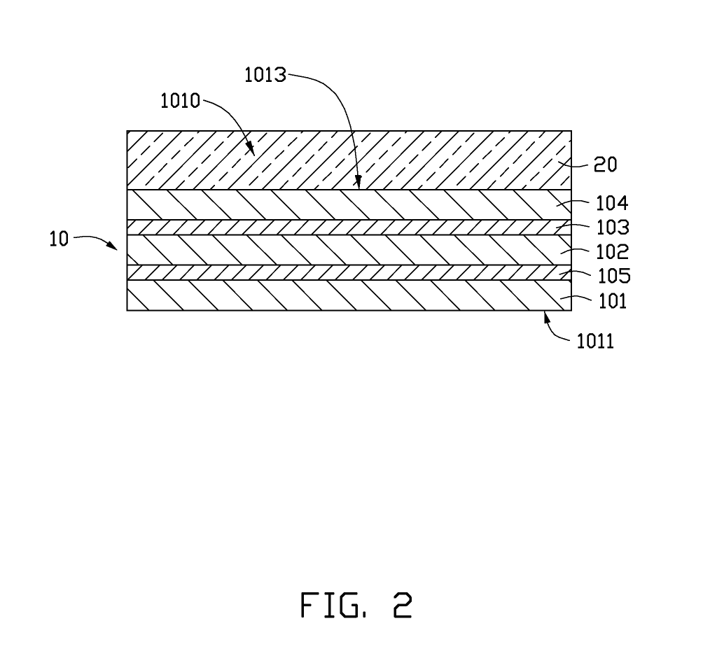

Block 41: referring to FIG. 2, a laminated structure 10 is provided. The laminated structure 10 includes a bottom surface 1011 and an opposite top surface 1013. A nanoimprinted material 20 is coated on a side 1010 opposite to the bottom surface 1011 of the laminated structure 10.

The laminated structure 10 includes a substrate 101, a first semiconductor layer 102, an active layer 103 and a second semiconductor layer 104. The first semiconductor layer 102, the active layer 103 and the second semiconductor 104 are formed over the substrate 101 in sequence. The substrate 101 can be dielectric. The substrate 101 can be made of sapphire (Al₂O₃), silicon carbide (SiC), silicon (Si), gallium nitride (GaN), or zinc oxide (ZnO), etc. Before the first semiconductor layer 102 is formed, a buffer layer 105 is formed on the substrate 101. The buffer layer 105 can decrease the degree of lattice mismatch between the first semiconductor layer 102 and the substrate 101. The buffer layer 102 can be made of AlₓGa₁₋ₓN (0≦x≦1) or AlₓGa_{y}In_{z}N (0≦x≦1. 0≦y≦1. 0≦z≦1, and x+y+z=1), etc. Accordingly, the first semiconductor layer 102 is formed on the buffer layer 105. In this embodiment, the first semiconductor layer 102 is an N-type doped semiconductor layer, and the second semiconductor layer 104 is a P-type doped semiconductor layer. The N-type doped semiconductor layer can be made of AlₓGa₁₋ₓN (0≦x<1), and doped with an N-type impurity. There are no particular limitations on the n-type impurity, and suitable examples include silicon (Si), germanium (Ge), or tin (Sn), etc. The active layer 103 that is laminated on the top of the first semiconductor layer 102, the active layer 103 may adopt a single quantum well structure, a multiple quantum well structure, or the like. The P-type doped semiconductor layer can be made of AlₓGa₁₋ₓN (0≦x<1), and doped with a P-type impurity, the P-type impurity can be made of magnesium (Mg), zinc (Zn) or beryllium (Be), etc. In an alternative embodiment, the first semiconductor layer 102 and the second semiconductor layer 104 can be a P-type doped semiconductor layer and an N-type doped semiconductor layer, respectively.

In this embodiment, the nanoimprinted material 20 is coated on the top surface 1013 of the second semiconductor layer 104, which is also the top surface 1013 of the laminated structure 10.

The nanoimprinted material 20 is made from a UV (ultra violet) curing material or a thermal curing material. The nanoimprinted material 20 is originally gelatinous, and turns into solid after absorbing enough energy. In details, the UV curing material turns from gel into solid after absorbing enough UV light, and the thermal curing material turns from gel into solid after absorbing enough heat.

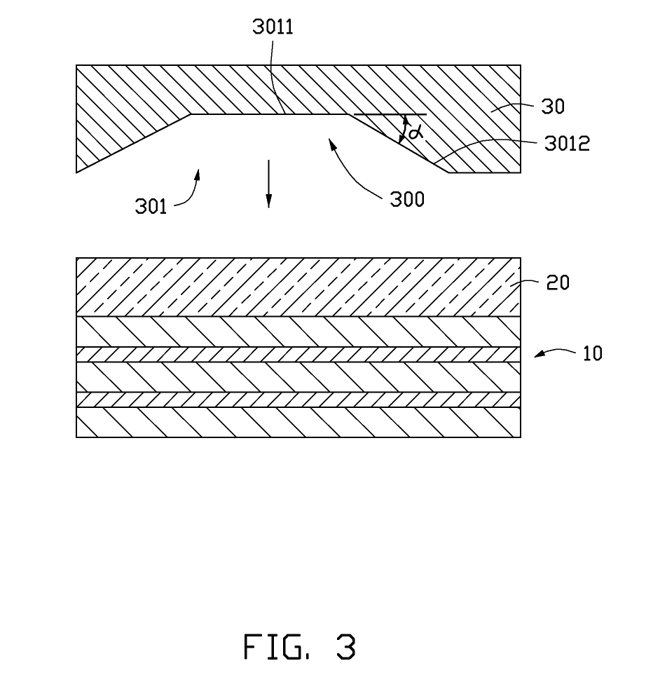

Block 42: referring to FIG. 3, an imprinted mold 30 is provided. The imprinted mold 30 presses the nanoimprinted material 20 coated on the laminated structure 10. The imprinted mold 30 has a patterned structure 300. In the depicted embodiment, the patterned structure 300 is a recess 301. The recess 301 has a ladder-shaped cross-section. The recess 301 includes a bottom surface 3011 and a flank 3012. An acute angle α between a plane where the bottom surface 3011 is located and the flank 3012 is less than 45°.

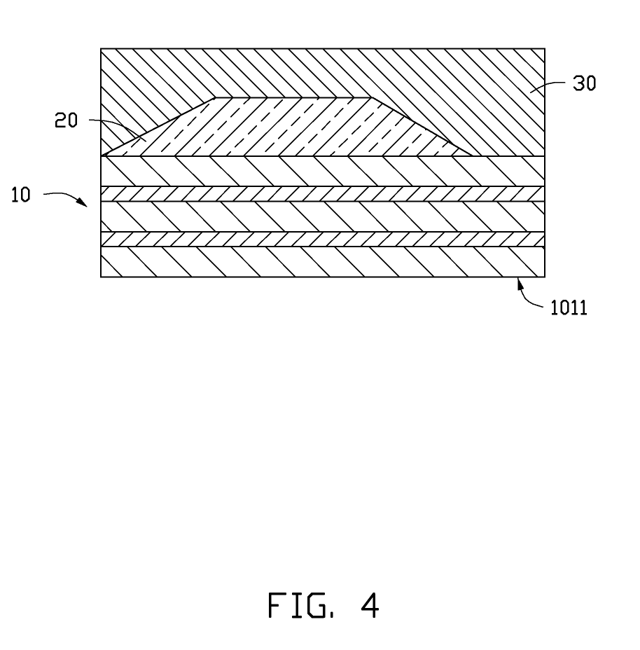

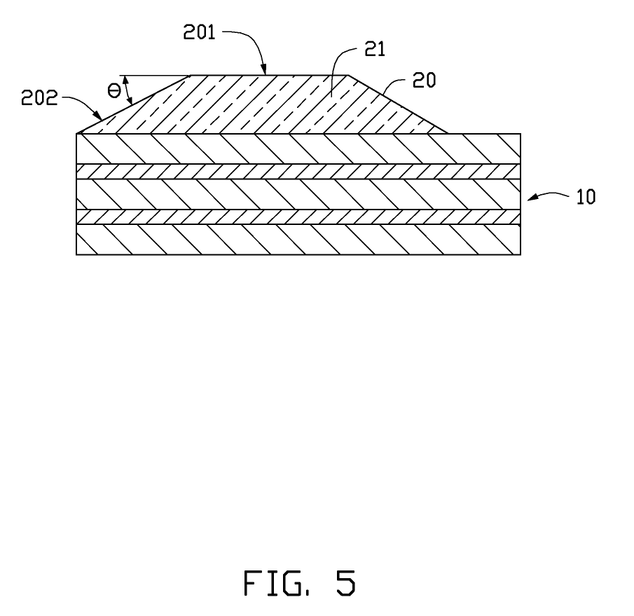

Block 43: referring to FIGS. 4 and 5, curing the nanoimprinted material 20 and then removing the imprinted mold 30.

In this embodiment, the nanoimprinted material 20 is the UV curing material. The nanoimprinted material 20 is radiated by the UV light and turns into solid after absorbing enough UV light. After the imprinted mold 30 is removed, an interim structure 21 made from the nanoimprinted material 20 is obtained. A shape of the interim structure 21 is the same as the shape of the patterned structure 300. Refer to FIG. 5, the cured nanoimprinted material 20 has a top surface 201 and a flank 202, and an angle θ between a plane where the top surface 201 is located and the flank 202 is less than 45°. In an alternative embodiment, the nanoimprinted material 20 is the thermal curing material, the nanoimprinted material 20 is heated up by an oven or microwave and turns into solid after absorbing enough heat.

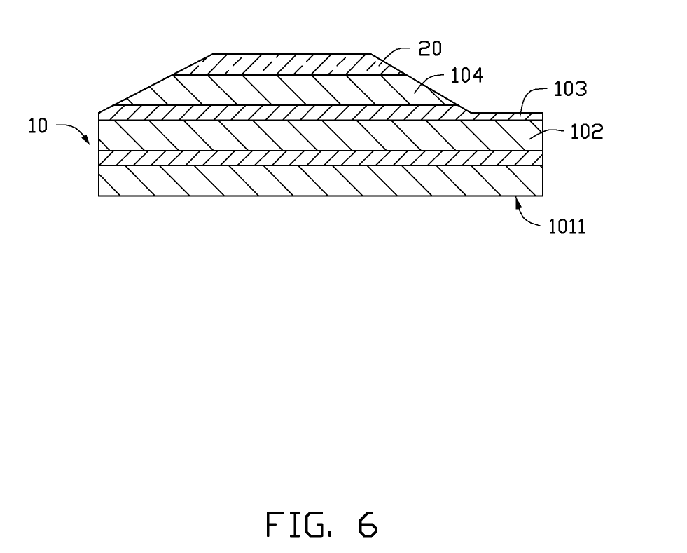

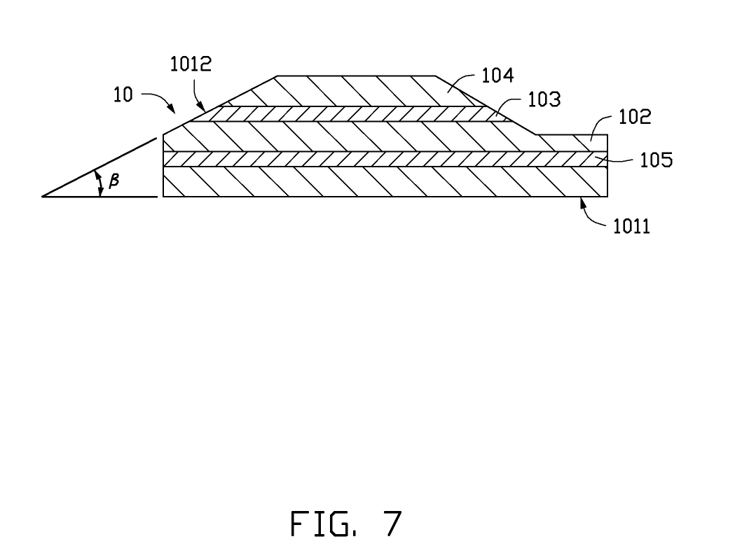

Block 44: referring to FIGS. 6 and 7, the nanoimprinted material 20 and the laminated structure 10 are etched by an inductively coupled plasma etching system or reactive ion beam etching system. FIG. 6 shows a structure obtained at a specific time during the etching process. At the specific time, a part of the nanoimprinted material 20 remains on the second semiconductor layer 104. Since the etching speed of all parts of the nanoimprinted material 20 and the laminated structure 10 are equal to each other, cross-section shapes of the nanoimprinted material 20 and/or the laminated structure 10 remains the same as the patterned structure 300 (i.e., the interim structure 21). FIG. 7 shows the etched laminated structure 10 after the etching process. In the etched laminated structure 10, the nanoimprinted material 20 is totally removed, and a part of the second semiconductor layer 104 and the active layer 103 are also removed to expose a part of the first semiconductor layer 102. As mentioned before, a cross-section shape of the etched laminated structure 10 is the same as the cross-section shape of the interim structure 21. An angle β of an inclined side 1012 and the bottom surface 1101 is less than 45°, which is according to the angle α between the bottom surface 3011 and the flank 3012 of the patterned structure 300.

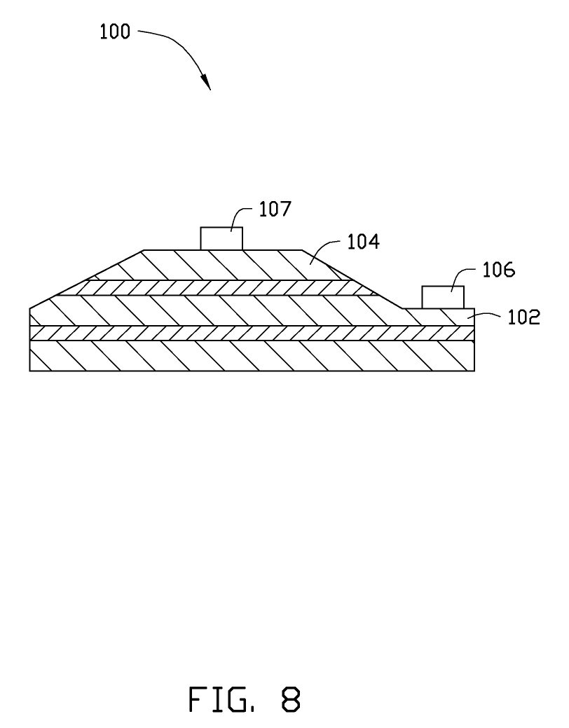

Block 45: referring to FIG. 8, electrodes 106, 107 are formed on the etched laminated structure 10, thereby forming the LED chip 100. The laminated structure 10 can be a vertical structure or a lateral structure. In this embodiment, the laminated structure 10 is a lateral structure. A first electrode 106 is formed on the first semiconductor 102 and a second electrode 107 is form on the second semiconductor 104.

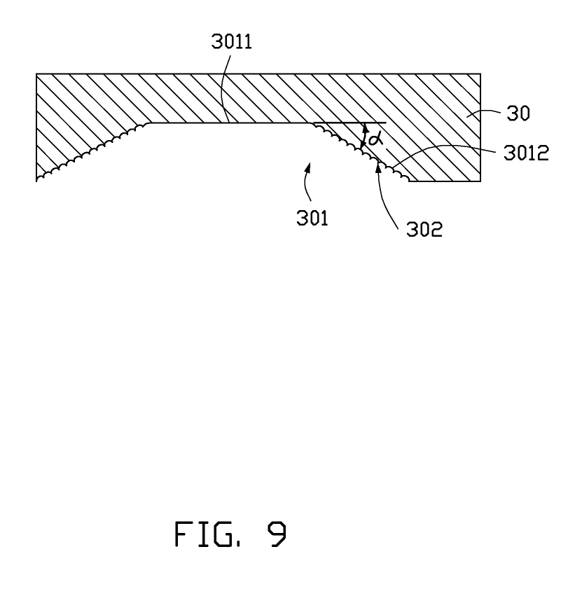

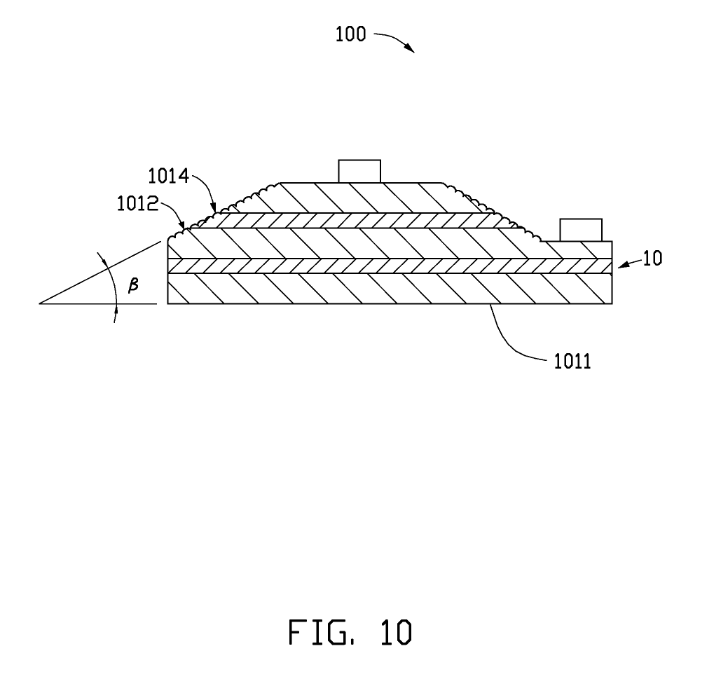

Referring to FIGS. 9 and 10, a three-dimensional structure 302 can be formed on the flank 3012 to weaken total reflection and improve the light extraction efficiency of the LED chip 100. In this embodiment, a cross-section of the three-dimensional structure 302 is a continuous arc. In this embodiment, the inclined side 1012 comprises a three-dimensional structure 1014, a cross-section of the three-dimensional structure 1014 is a continuous arc, and the angle β between the inclined side 1012 and the bottom surface 1011 is less than 45°.

The LED chip 100 includes the laminated structure 10 and electrodes 106, 107, the laminated structure 10 include the inclined side 1012 and the bottom surface 1011, and the angle β between the inclined side 1012 and the bottom surface 1011 is less than 45°.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A method of manufacturing an LED chip, comprising:
providing a laminated structure with a nanoimprinted material formed on the laminated structure;
providing an imprinted mold with a patterned structure for pressing the nanoimprinted material, wherein the patterned structure has a ladder-shaped cross-section with a bottom surface and a flank having an angle less than 45° defined therebetween;
curing the nanoimprinted material and then removing the imprinted mold, with a corresponding patterned structure imprinted on the cured nanoimprinted material;
etching the nanoimprinted material and the laminated structure; and
forming electrodes on the etched laminated structure.

2. The method of claim 1, wherein the laminated structure comprises a substrate, a first semiconductor layer, an active layer and a second semiconductor layer, and the first semiconductor layer, the active layer and the second semiconductor is successively formed over the substrate.

3. The method of claim 1, wherein the nanoimprinted material is a UV curing material or a thermal curing material.

4. The method of claim 3, wherein the flank of the recess comprises a three-dimensional structure.

5. The method of claim 1, wherein the nanoimprinted material and the laminated structure are etched by inductively coupled plasma etching system or reactive ion beam etching system.

6. The method of claim 1, wherein before forming the first semiconductor layer, a buffer layer is formed on the substrate.

7. A method of manufacturing LED chips, comprising:
providing a laminated structure with a nanoimprinted material coated thereon;
providing an imprinted mold with a patterned structure for pressing and curing the nanoimprinted material, wherein the patterned structure is configured as a plurality of ladder-shaped cross-section recess, each recess comprising a bottom surface and a flank with an angle less than 45° defined therebetween;
removing the imprinted mold with a corresponding patterned structure imprinted on the cured nanoimprinted material; and
etching the nanoimprinted material and the laminated structure to obtain an etched laminated structure having a same cross-section shape with the patterned structure.

8. An LED chip, comprising:
a substrate; and
a first semiconductor layer, an active layer and a second semiconductor layer, being successively formed over the substrate;
wherein a lateral surface of the first semiconductor layer, the active layer and the second semiconductor layer is inclined to a bottom surface of the substrate, and the inclined angle is less than 45°.

9. The LED chip of claim 8 further comprising a buffer layer formed on the substrate, and the first semiconductor layer is formed on the buffer layer.

10. The LED chip of claim 8, wherein the lateral surface is configured as a three-dimensional structure.

11. The LED chip of claim 10, wherein the three-dimensional structure is a continuous arc.
